(19) United States
(12) Patent Application Publication
(10) Pub. No.: US 2006/0005093 A1
(43) Pub. Date: Jan. 5, 2006

(54) Comparator for circuit testing

(76) Inventor: Tom Leslie, Northampton (GB)

Correspondence Address: TEXAS INSTRUMENTS INCORPORATED, P O BOX 655474, M/S 3999, DALLAS, TX, 75265, US

(21) Appl. No.: 11/151,574

(22) Filed: Jun. 13, 2005

(30) Foreign Application Priority Data
Jun. 12, 2004 (GB) 0413146.2

(51) Int. Cl. G06F 11/00; G01R 31/28

(52) U.S. Cl. 714/735

(57) ABSTRACT

There is provided a test circuit comprising a test signal input for receiving a test signal, a hysteretic comparator having first and second comparison inputs and an output indicating the result of the comparison, and a delay circuit. The first comparison input is connected to the test signal input and the second comparison input is connected to receive the test signal on the test signal input via the delay circuit, the comparator thereby comparing the test signal on the test signal input with a delayed version of itself. Also provided is a test system comprising a first integrated circuit including the abovementioned test circuit, a second integrated circuit comprising test signal generation circuitry, and an interconnection between the generation circuitry and the test signal input of the test circuit of the first integrated circuit.

### BACKGROUND OF THE INVENTION

IEEE1149.1 is the “JTAG” specification and covers the addition of minimal amounts of circuitry to all chip I/Os (irrespective of the chip function of the component) so that these I/Os may be used to verify the integrity of loaded PCBs and sub-assemblies.

While this was originally intended to cover all possible signal interconnects, suppliers were allowed to designate certain I/Os as “analogue”, in which case they could not and would not be covered with a JTAG test.

### SUMMARY OF THE INVENTION

As ever more complicated systems were integrated, the number of boards which could not be fully checked started to increase because it became more likely that at least some of the signals would be “analogue”. IEEE1149.6 was written to address this shortfall, by extending the class of I/Os covered to specifically include
1. differential signals
2. ac-coupled signals.

A feature of the specification for differential signals is that in testing one component of such a signal, the other component may not be used or even assumed.

In the invention the approach to testing such a signal is to compare a signal with a delayed version of itself.

Test circuits according to the present invention are defined in the appended claims.

### BRIEF DESCRIPTION OF THE DRAWINGS

An example of the present invention will now be described with reference to the accompanying drawings, of which:

FIGS. 1a and 1b show test signals.

FIG. 2 is a block diagram of a test circuit according the invention.

FIG. 3 is a circuit diagram of an implementation of a comparator used in the invention.

FIG. 4 shows a block diagram illustrating the use of the invention to test a circuit board connection.

### DETAIL DESCRIPTION

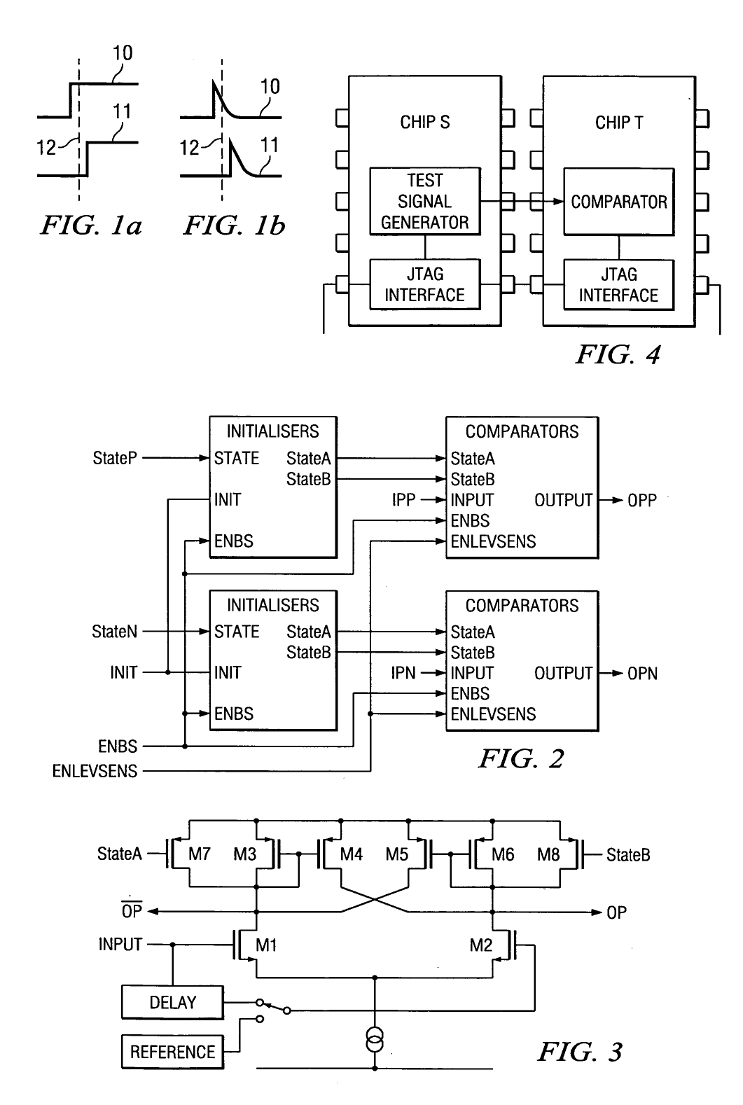

The present invention tests a signal by comparing it with a delayed version of itself. Refer now to FIG. 1.

A delayed version 11 of a signal 10 may be compared at point 12 (FIG. 1(a). In this way the process in self referencing and no a priori knowledge of signal level is needed.

For an ac coupled signal, the level will not be maintained and two impulses may be compared nonetheless. (FIG. 1(b)).

The invention uses a comparator circuit to compare the original signal. A number of desirable attributes for the comparator circuit are as follows:

It should be self referencing—since the reference voltage value against which to compare the signal may be unknown. (e.g. for one part of a differential signal the reference (i.e. the other part) is also external and further the use of the other part of a differential signal as a reference is not permitted by IEEE 1149.6). The exemplary self-referencing comparator compares a signal against a delayed version of itself to detect whether any changes have occurred (edge-detection)

It should have hysteresis—since if it is self referenced, most of the time the input to the comparator will be zero and the output state would otherwise be undetermined. Furthermore, maintenance of an input level will not occur in the case of ac coupling.

To simplify the process of carrying out the board level test the output state of the comparator must be capable of being initialised

The comparator should also be capable of operating in a level-sensitive mode, in which the input test signal is compared to a reference level. This is for backwards compatibility with 1149.1; however it also allows certain further tests to be carried out (mainly the integrity of ac coupling capacitors where these are used).

FIG. 2 shows a block diagram of two exemplary comparator circuits and associated control circuitry. Two circuits are shown because the example is for the case of a differential input signal which of course has two separate inputs. The comparators nonetheless test the signals on the two inputs separately and do not use one as a reference level for the other. The invention is nonetheless applicable to other kinds of analogue signals including those that require only a single input for which, of course only a single comparator need be used.

The basic structure subdivides into two parts, an initialiser module and a comparator module as shown in FIG. 2. The signals marked in the Figure are as follows:

TABLE 1

| | |
|---|---|
| IPP | Analogue +ve data input (from RXP via coupling |
| | network) |
| IPN | Analogue −ve data input (from RXN via coupling |
| | network) |
| StateP | State to which output OPP is to be initialised |
| StateN | State to which output OPN is to be initialised |
| INIT | Initialisation edge, which transfers StateP and StateN to |
| | IPP and IPN respectively |
| ENBS | Enables the comparators |
| ENLEVSENS | Enables the level sensing mode |
| OPP | Comparator output |
| OPN | Comparator output. |

The circuit block of FIG. 2 comprises two independent comparators with their initialisation. There are four sub-modules within the block: two instances of an initialiser and two instances of the actual comparator.

The only signals shared by the two comparators are INIT, ENBS and ENLEVSENS. ENBS “high” enables both comparators, which will power up in edge-sensitive mode. If ENLEVSENS is also high, then the comparators will be placed into the level-sensitive mode, switching against an internal reference. Thus valid modes for the module are as given in Table 2.

TABLE 2
Operating modes for the circuit of FIG. 2

| ENBS | ENLEVSENS | Operating Mode |
|---|---|---|
| 0 | 0 | Module powered down |
| 0 | 1 | Meaningless - don't permit it |
| 1 | 0 | Module powered both comparators |
| | | in edge sensitive mode |
| 1 | 1 | Module powered both comparators |
| | | in level-sensitive mode |

When the module is powered up in edge-sensitive mode both outputs of a comparator (OPP and OPN) are initially undetermined. The hysteresis within the comparators guarantees that they will be at one rail or the other (NB they will not necessarily be complementary). The comparators may be initialised to the States set on StateP and StateN by a rising edge on INIT. (Once again there is no need for StateP and StateN to be complementary).

Each initializer sub-module has a State and INIT input and StateA and StateB outputs. StateA and StateB are both “high” in the absence of an edge on INIT. Given a positive-going edge on INIT, then for a short period
StateA=State
StateB=\overline{State}
   i.e. a short negative pulse on one of stateA and stateB is generated.

This combination of internal signals force the associated comparator output, so that the net result is as shown in Table 3

TABLE 3
Possible initialisations in edge-sensitive mode

Rising edge
on INIT causes

| StateP | StateN | OPP | OPN |
|---|---|---|---|
| 0 | 0 | X->0 | X->0 |
| 0 | 1 | X->0 | X->1 |
| 1 | 0 | X->1 | X->0 |
| 1 | 1 | X->1 | X->1 |

Once initialized, comparators will then respond to subsequent edges on IPP and IPN.

When the module is powered up in a level-sensitive mode, each comparator input (IPP and IPN) is compared against a fixed reference and the output states at power-up will be determined by the values of IPP and IPN compared with this fixed reference, allowing for the in-built hysteresis of the comparators.

Whatever the actual output levels at power-up, the comparators can be initialised by the same procedure as was used for edge-sensitive mode. That is the combination of StateP, StateN and INIT will result in the initialazations shown in Table 4.

TABLE 4
Possible initializations in level-sensitive mode

Rising edge
on INIT causes

| StateP | StateN | OPP | OPN |
|---|---|---|---|
| 0 | 0 | 0, 1, X->0 | 0, 1, X->0 |
| 0 | 1 | 0, 1, X->0 | 0, 1, X->1 |
| 1 | 0 | 0, 1, X->1 | 0, 1, X->0 |
| 1 | 1 | 0, 1, X->1 | 0, 1, X->1 |

Note that while the appropriate combination of INIT, StateP and StateN will result in the behavior shown in Table 4; once the initialization sequence is finished the comparators will immediately become responsive to the levels on their inputs (allowing for the in-built hysteresis), and therefore the values on OPP and OPN may immediately change again.

FIG. 3 shows a detailed implementation of each of the comparator circuits of FIG. 2.

In FIG. 3 devices M1 and M2 form a transconductance pair which compares an input signal either against a delayed version of itself (edge-sensitive mode), or against a fixed voltage (level-sensitive mode) as determined by the selector switch which connects the gate of M2 either to the delayed version of the input signal or to a reference. The current outputs from this pair drive the load block comprising M3, M4, M5, and M6, where current hysteresis is provided by the size ratio of M3 to M4 (and M5 to M6). Transistors M3 and M4 are connected in a current mirror configuration. M4 is a bigger transistor than M3, i.e. M4 provides more current than M3. Similarly M6 and M5 are in a current mirror configuration with M5 being sized to provide more current than M6.

M7 and M8 receive inputs from the Initializer block of 2 and determine the starting State of the comparator. (After the negative pulse of StateA or StateB has been received these two transistors are switched off.)

In one test, signals StateA and StateB are used to initialize the comparator with output OP high and output OP\ low. In this state the current source connected to M1 and M2 draws current through M1 and M3 and also through M2 and M4. Transistors M5 and M6 are switched off. While the input to the comparator remains steady M1 and M2 have a similar bias and draw the same current, with the result that the output state at nodes OP and OP\ remain unchanged. M4 being a larger transistor than M3 ensures that this occurs.

A connection to the circuit (e.g. across a circuit board) is tested by transmitting to the input of the comparator a negative going edge. For a short period this results in the input to the gate of M1 being lower than that of M2 and therefore M1 passes less current than M2. The current from current source therefore is switched to M2 which then draws down node OP and the comparator switches to the opposite state in which OP is low and OP\ is high confirming that an edge has been received. The comparator is hysteretic and so requires a reasonable difference on the gates of M1 and M2; with only a small difference because M4 is bigger than M3, M4 can easily take up the extra current drawn by M2 and the output state OP remains unchanged—i.e. the hysteresis is provided. Once switched the levels of OP and OP remain stable due to the hysteresis of the comparator.

If a test with a positive going edge as input is desired then the comparator can be initialised in the opposite state.

Not shown in FIG. 3 is the biasing for the current circuit in order to place the comparator in its operating region. Preferably the output from the comparator is connected to a differential to single-ended converter (not shown) and preferably the output of that is connected to a buffer (also not shown).

The way in which the required control signals can be loaded to the circuit will be known to those familiar with JTAG testing.

During testing the comparator can also be initialized to its other state by an input transition in the opposite direction.

FIG. 4 shows a test arrangement for testing an analogue connection (e.g. one part of a differential signal) across a circuit board or the like using the invention. On a first integrated circuit Chip S a test signal generator is provided; often no extra circuitry is required since the existing output circuits can be controlled to provide the signal. The test signal may for example be an edge as described above. The test signal is caused to be sent by the JTAG control circuitry or interface on the chip as will be known to those familiar with JTAG testing. On the other integrated circuit Chip T a comparator is provided to receive the test signal, which is transmitted via a conductor connecting the two integrated circuits. If necessary the comparator is initialized under the control of the JTAG test interface on Chip T. On receiving the test signal the comparator responds and the result is transferred to the JTAG interface from where it can be accessed as will be known to those familiar with JTAG testing.

While the invention has been shown and described with reference to preferred embodiments thereof, it is well understood by those skilled in the art that various changes and modifications can be made in the invention without departing from the spirit and scope of the invention as defined by the appended claims.

While the invention has been shown and described with reference to preferred embodiments thereof, it is well understood by those skilled in the art that various changes and modifications can be made in the invention without departing from the spirit and scope of the invention as defined by the appended claims.

1. A test circuit comprising,
a test signal input for receiving a test signal,
a hysteretic comparator having first and second comparison inputs and an output indicating the result of the comparison,
a delay circuit,
wherein the first comparison input is connected to the test signal input and the second comparison input is connected to receive the test signal on the test signal input via the delay circuit, the comparator thereby comparing the test signal on the test signal input with a delayed version of itself.

2. A test circuit according to claim 1 wherein the comparator has an initialization input to which it is responsive to place the comparator output in a predefined state.

3. A test circuit according to claim 2 comprising initialization circuitry connected to provide an initialization signal to the initialization input.

4. A test circuit according to claim 1 further comprising:
a reference voltage generator having a reference voltage output, and
a selector operable to connect the second comparison input of the comparator either to the reference voltage output or to the delay circuit.

5. An integrated circuit comprising a test circuit according to claim 1.

6. An integrated circuit according to claim 5 comprising a JTAG interface connected to control the test circuit and to receive the output of the comparator.

7. A test system comprising:
a first integrated circuit according to claim 5,
a second integrated circuit comprising test signal generation circuitry,
an interconnection between the generation circuitry and the test signal input of the test circuit of the first integrated circuit.

8. An integrated circuit comprising a test circuit according to claim 2.

9. An integrated circuit comprising a test circuit according to claim 3.

10. An integrated circuit comprising a test circuit according to claim 4.

11. A test system comprising:
a first integrated circuit according to claim 6,
a second integrated circuit comprising test signal generation circuitry,
an interconnection between the generation circuitry and the test signal input of the test circuit of the first integrated circuit.

12. A test circuit according to claim 2 further comprising:
a reference voltage generator having a reference voltage output, and
a selector operable to connect the second comparison input of the comparator either to the reference voltage output or to the delay circuit.

13. A test circuit according to claim 3 further comprising:
a reference voltage generator having a reference voltage output, and
a selector operable to connect the second comparison input of the comparator either to the reference voltage output or to the delay circuit.
